(19) United States
(12) Patent Application Publication
(10) Pub. No.: US 2024/0276695 A1
(43) Pub. Date: Aug. 15, 2024

(54) FLUX TRANSFER APPARATUS, FLUX TRANSFER METHOD, AND MOUNTING APPARATUS

(71) Applicant: SHINKAWA LTD., Tokyo (JP)

(72) Inventor: Shinichi YOSHIDA, Tokyo (JP)

(73) Assignee: SHINKAWA LTD., Tokyo (JP)

(21) Appl. No.: 18/681,861

(22) PCT Filed: Aug. 13, 2021
(86) PCT No.: PCT/JP2021/029839

§ 371 Date: Feb. 7, 2024

(51) Int. Cl. H05K 13/08; B23K 1/20; B23K 101/36; H05K 13/04

(52) U.S. Cl. CPC H05K 13/0812; B23K 1/203; H05K 13/0465; B23K 2101/36

(57) ABSTRACT

A flux transfer apparatus (1) includes: a transfer stage (21), storing a flux; a holding tool (13), holding an electronic component (CP) by using a holding surface (13a), so that an electrode formation surface (CPA) of the electronic component (CP) is immersed into the flux stored in a transfer stage (21); an image capturing part (31), obtaining a captured image of at least one of the electrode formation surface (CPA) of the electronic component (CP) after flux transfer and the transfer stage (21) after flux transfer; and a detection part (51), detecting an inclination of the holding surface (13a) with respect to the transfer stage (21) based on the captured image.

### TECHNICAL FIELD

The invention relates to a flux transfer apparatus, a flux transfer method, and a mounting apparatus.

### RELATED ART

In general, solder bonding is widely used in electronic component mounting by using a flip chip bonding method, etc. In the flip chip bonding method, in order to facilitate the connection between the solder and an electrode, a method in which a flux (an oxide film removal agent, a surfactant, etc.) is transferred onto an electrode formation surface of the electronic component, and then the electronic component is mounted on a substrate is used. Since the amount of flux affects soldering quality, a flux transfer apparatus may be provided with a mechanism that detects a transfer defect.

For example, Patent Document 1 discloses a flux transfer apparatus including: a lighting that illuminates a flux immersion area of a transfer stage with light; an image capturing means that captures an image of the flux immersion area; and a control means that compares the image captured by the image capturing means with an image recorded in advance and determines whether the image captured by the image capturing means is favorable.

### PRIOR ART DOCUMENTS

### Patent Documents

[Patent Document 1] Japanese Patent No. 4960160.

### SUMMARY OF INVENTION

### Technical Problem

According to the invention recited in Patent Document 1, a flux transfer defect due to poor flatness during flux deposition can be prevented, and a mounting defect of an electronic component onto a substrate can be reduced.

However, in the case where an electrode formation surface of the electronic component is inclined with respect to the flux provided on the transfer stage, it is possible that the resonance apparatus recited in Patent Document 1 is unable to sufficiently suppress the transfer defect.

The invention has been made in view of the above issue, and an objective of the invention is to provide a flux transfer apparatus, a flux transfer method, and a mounting apparatus capable of suppressing a transfer defect.

### Solution to Problem

A flux transfer apparatus according to an aspect of the invention transfers a flux to an electrode formation surface of an electronic component and includes: a transfer stage, storing the flux; a holding tool, holding the electronic component by using a holding surface, so that the electrode formation surface of the electronic component is immersed into the flux stored in the transfer stage; an image capturing part, obtaining a captured image of at least one of the electrode formation surface of the electronic component after flux transfer and the transfer stage after flux transfer; and a detection part, detecting an inclination of the holding surface with respect to the transfer stage based on the captured image.

According to the aspect, for example, by repetitively carrying out test production, so that the inclination of the holding surface with respect to the transfer stage is substantially zero, the transfer defect of the flux can be suppressed. In particular, in the case where the size of the electronic component is large, that is, in the case where the inclination of the holding surface with respect to the transfer stage has a significant influence on the transfer defect of the flux at the end of the electrode formation surface, the transfer defect can be effectively suppressed.

In the above aspect, the flux transfer apparatus may include a first adjustment part configured to be able to adjust a posture of the holding tool based on the inclination.

In this way, the variation of the liquid surface of the flux due to a posture change of the transfer stage can be suppressed. Therefore, the occurrence of a transfer defect due to a posture change of the transfer stage can be suppressed.

In the above aspect, the flux transfer apparatus may include a second adjustment part configured to be able to adjust a posture of the transfer stage based on the inclination.

In this way, the inclination of the holding tool with respect to the transfer stage can be adjusted without adjusting the posture of the holding tool. Therefore, the occurrence of a displacement error at the time of adjusting the posture of the holding tool can be suppressed.

In the above aspect, the image capturing part may capture an image of the electrode formation surface of the electronic component after flux transfer from a bottom.

In this way, based on the captured image obtained by the image capturing part, not only the inclination of the electronic component with respect to the transfer stage can be detected, a position deviation of the electronic component in an in-plan direction of the electrode formation surface can also be detected.

In the above aspect, the detection part may compare the captured image and a reference image obtained from an electrode formation surface of an electronic component after a flux is normally transferred.

In this way, even for a flux having low visibility and being difficult to detect through an image analysis, the detection can be accurately carried out by using an image analysis on the differential between the captured image and the reference image.

In the above aspect, the detection part may obtain an image of at least one sub area from the captured image, and perform comparison with the reference image for the at least one sub area.

In this way, compared with the case where the captured image of the entire electrode formation surface is compared with the reference image, the time required for detection can be reduced.

In the above aspect, the at least one sub area may include a corner sub area provided at a corner of the electrode formation surface.

In this way, when the inclination of the holding tool with respect to the transfer stage changes, by determining whether the transfer of the flux at the corner sub area with the greatest displacement is successful, the transfer defect of the flux on the entire electrode formation surface can be quickly evaluated.

In the above aspect, the at least one captured area may include a band-shaped area extending along a long side or a short side of the electrode formation surface.

In this way, by specifying the position of a transfer flux defect in the belt-shaped sub area, the angle of the inclination of the holding tool with respect to the transfer stage can be calculated.

In the above aspect, the holding tool may be a bonding tool mounting the electronic component to a target.

A flux transfer method according to another aspect of the invention transfers a flux to an electrode formation surface of an electronic component and includes: storing the flux in a transfer stage; holding the electronic component by using a holding surface of the holding tool; immersing the electrode formation surface of the electronic component into the flux stored in the transfer stage; obtaining a captured image of at least one of the electrode formation surface of the electronic component after flux transfer and the transfer stage after flux transfer; and detecting an inclination of the holding surface with respect to the transfer stage based on the captured image.

According to the aspect, for example, by repetitively carrying out test production, so that the inclination of the holding surface with respect to the transfer stage is substantially zero, the transfer defect of the flux can be suppressed. In particular, in the case where the size of the electronic component is large, that is, in the case where the inclination of the holding surface with respect to the transfer stage has a significant influence on the transfer defect of the flux at the end of the electrode formation surface, the transfer defect can be effectively suppressed.

In the above aspect, the flux transfer method may further include adjusting a posture of the transfer stage or the holding tool based on the inclination.

In the above aspect, the flux transfer method may further include: opening the electronic component without mounting the electronic component to a target, and immersing an electrode formation surface of another electronic component into the flux stored in the transfer stage.

In the above aspect, the flux transfer method may further include: immersing the electronic component into the flux stored in the transfer stage again.

In this way, by reusing the electronic component in which the transfer of the flux is insufficient, the loss of the electronic component can be reduced.

A mounting apparatus according to another aspect of the invention mounts an electronic component in which a flux is transferred onto an electrode formation surface to a target and includes: a transfer stage, storing the flux; a mounting tool, holding the electronic component by using a holding surface, so that the electrode formation surface of the electronic component is immersed into the flux stored in the transfer stage, and mounting the electronic component to the target: an image capturing part, obtaining a captured image of at least one of the electrode formation surface of the electronic component after flux transfer and the transfer stage after flux transfer; and a detection part, detecting an inclination of the holding surface with respect to the transfer stage based on the captured image.

According to the aspect, for example, by repetitively carrying out test production, so that the inclination of the holding surface with respect to the transfer stage is substantially zero, the mounting defect due to the transfer defect of the flux can be suppressed.

### Effects of Invention

According to the invention, a flux transfer apparatus, a flux transfer method, and a mounting apparatus capable of suppressing transfer defects can be provided.

### BRIEF DESCRIPTION OF DRAWINGS

FIG. 1 is a schematic view illustrating a configuration of a flux transfer apparatus according to a first embodiment.

FIG. 2 is a schematic view illustrating a configuration of a posture control unit according to the first embodiment.

FIG. 3 is a flowchart schematically illustrating a flux transfer method using the flux transfer apparatus according to the first embodiment.

FIG. 4 is a schematic view illustrating Step S20.

FIG. 5 is a view illustrating an example of a captured image of an electrode formation surface and a sub area.

FIG. 6 is a view illustrating another example of a captured image of an electrode formation surface and a sub area.

FIG. 7 is a schematic view illustrating a configuration of a posture control unit according to a second embodiment.

FIG. 8 is a schematic view illustrating a configuration of a posture control unit according to a third embodiment.

### DESCRIPTION OF EMBODIMENTS

In the following, the embodiments of the invention are described with reference to the drawings. The drawings of the embodiments are examples, and the dimensions and shapes of respective parts are schematic, and the technical scope of the invention should not be construed as being limited to the embodiments.

### Embodiment 1

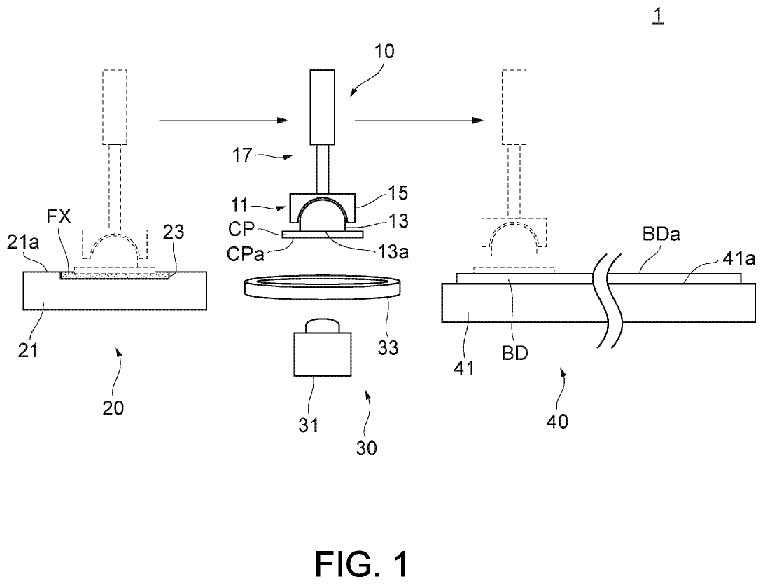

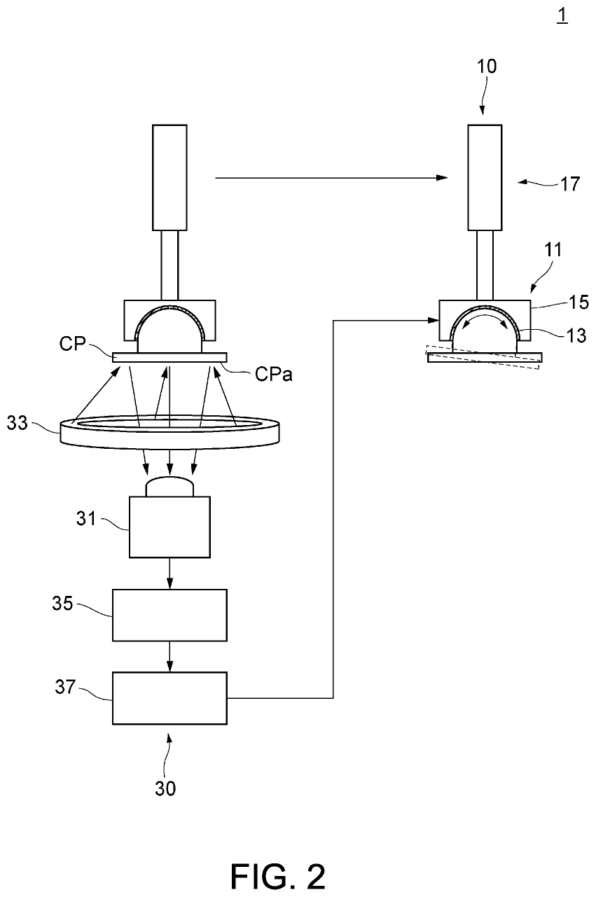

Firstly, the configuration of a flux transfer device 1 according to the first embodiment of the invention is described with reference to FIGS. 1 and 2. FIG. 1 is a schematic view illustrating a configuration of a flux transfer apparatus according to the first embodiment. FIG. 2 is a schematic view illustrating a configuration of a posture control unit according to the first embodiment.

The flux transfer apparatus 1 includes a conveyance unit 10, a transfer unit 20, a posture control unit 30, and a mounting unit 40.

The conveyance unit 10 conveys an electronic component CP. Specifically, the conveyance unit 10 is configured to be able to convey the electronic component CP between the transfer unit 20 and the posture control unit 30 and between the posture control unit 30 and the mounting unit 40. The conveyance unit 10 conveys the electronic component CP taken out from a feeder (not shown) to the transfer unit 20, conveys the electronic component CP to which a flux FX is transferred to the posture control unit 30, and conveys the electronic component CP for which an image of an electrode formation surface CPa is captured to the mounting unit 40. The conveyance unit 10 may also convey the electronic component CP for which the image of the electrode formation surface CPa is captured to the transfer unit 20 again, and may also open the electronic component CP to a tray (not shown).

The conveyance unit 10 includes a bonding head 11 and an actuator 17. The bonding head 11 holds the electronic component CP. The actuator 17 moves the bonding head 11 in three axial directions.

The bonding head 11 includes a holding tool 13 and an inclination adjustment mechanism 15.

The holding tool 13 detachably holds the electronic component CP on a holding surface 13a. The holding tool 13, for example, is a suction collet holding the electronic component CP through vacuum suction. In the case of the suction collet, for example, the holding surface 13a is a flat surface on which a suction hole is provided. The electronic component CP may contact the holding surface 13a to be held, and may also be held by a distance from the holding surface 13a. However, if the electronic component CP can be held so that the electrode formation surface CPa of the electronic component CP is immersed into the flux FX of the transfer stage 21, it is not required that the holding tool 13 be limited to the suction collet. The holding tool 13 is installed to the inclination adjustment mechanism 15.

The inclination adjustment mechanism 15 is configured to be able to adjust the posture of the holding tool 13.

The inclination adjustment mechanism 15, for example, sets the posture of the holding tool 13 with respect to the transfer stage 21, so that the surface of the flux FX stored in the transfer stage 21 and the electrode formation surface CPa of the electronic component CP can be substantially parallel to each other. The posture of the holding tool 13 with respect to the transfer stage 21, for example, is defined as the inclination of the holding surface 13a of the holding tool 13 with respect to the transfer surface 21a of the transfer stage 21. The inclination adjustment mechanism 15 is equivalent to an example of a first adjustment part according to the invention.

The inclination adjustment mechanism 15, for example, sets the posture of the holding tool 13 with respect to a mounting stage 41, so that the electrode formation surface CPa of the electronic component CP and a mounting surface BDa of a substrate BD are substantially parallel to each other. The posture of the holding tool 13 with respect to the mounting stage 41. for example, is defined as the inclination of the holding surface 13a of the holding tool 13 with respect to a placement surface 41a of the mounting stage 41.

The transfer unit 20 transfers the flux FX to the electrode formation surface CPa (a surface on a side where a bump electrode is formed) of the electronic component CP.

The transfer unit 20 includes the transfer stage 21.

An immersion area 23 is formed on the transfer surface 21a of the transfer stage 21. The immersion area 23 is a concave part formed with a predetermined depth. For example, after the flux FX coated on the transfer surface 21a of the transfer unit 20 is leveled by using a first squeegee, a second squeegee is used to scrapes off excessive flux FX from the transfer surface 21a. Accordingly, the flux FX is evenly stored in the immersion area 23. The surface of the flux FX is provided to be substantially flush with the transfer surface 21a of the transfer stage 21. The electrode formation surface PCa of the electronic component CP held by the holding tool 13 of the conveyance unit 10 is immersed with respect to the flux FX stored in the immersion area 23 of the transfer unit 20.

The posture control unit 30 detects the inclination of the holding surface 13a with respect to the transfer stage 21, and controls the posture of the holding tool 13 so that the inclination is substantially zero. In other words, based on the detected inclination, the posture of the holding tool 13 is changed, so that the surface of the flux FX of the transfer stage 21 and the electrode formation surface CPa of the electronic component CP are substantially parallel to each other.

The posture control unit 30 includes an image capturing part 31, a lighting 33, a detection part 35, and a control part 37.

The image capturing unit 31 captures an image of the electronic component CP held by the holding tool 13, and obtains a captured image of the electrode formation surface CPa after flux transfer. The image capturing part 31 is a CCD camera, for example. However, the image capturing unit 31 is not particularly limited, as long as the image capturing part 31 is able to obtain the captured image of the electrode formation surface CPa after flux transfer.

The lighting 33 illuminates the electrode formation surface CPa after flux transfer with light when the image capturing part 31 captures the image of the electronic component CP held by the holding tool 13. That is, the image capturing part 31 captures the image of the electrode formation surface CPa after flux transfer in a state of being illuminated by the lighting 33. The lighting 33, for example, is a ring lighting. However, the lighting 33 is not particularly limited as long as the lighting 33 is able to illuminate the electrode formation surface CPa after flux transfer with light.

The detection part 35 detects the inclination of the holding surface with respect to the transfer stage 21 based on the captured image obtained by using the image capturing part 31. A reference image obtained from an electrode formation surface of an electronic component after a flux is normally transferred is recorded in advance in the detection part 35. The detection part 35 compares the captured image obtained by using the image capturing part 31 with the reference image recorded in advance. In addition, by performing an image analysis on a differential between the captured image and the reference image, a transfer condition of the flux FX (whether the transfer is successful, the transfer amount, the transfer distribution, etc.) to the electrode formation surface CPa is evaluated.

The detection part 35, for example, obtains images of multiple sub areas from the captured image obtained by using the image capturing part 31, and compares each of the sub areas with the reference image. That is, the detection part 35 determines the transfer condition (whether the transfer is successful, the transfer amount, the transfer distribution, etc.) of the transfer flux FX for each sub area. For example, the detection part 35 calculates the orientation or the angle of the holding surface 13a with respect to the transfer stage 21 by associating the location information of each of the sub areas with the information relating to whether the transfer of the flux FX in each of the sub areas is successful. The number, areas, and shapes of the sub areas are not particularly limited, as long as the sub areas are smaller than the electrode formation surface CPa of the electronic component CP.

The sub areas obtained by the detection part 35 may also include, for example, a corner sub area provided at a corner of the electrode formation surface CPa. In the case where the angle of the holding tool 13 with respect to the transfer stage 21 changes, by determining whether the transfer of the flux FX is successful at the corner with the greatest displacement. whether the transfer of the flux FX in the entire electrode formation surface CPa is successful can be quickly determined. In addition, the sub areas obtained by the detection part 35 may include at least one of a band-shaped sub area provided along a long side of the electrode formation surface CPa over the entire width in the long side direction and a band-shaped sub area provided along a short side over the entire width in the long side direction. By determining the position of a transfer defect in the band-shaped sub area, the size of the angle of the holding tool 13 with respect to the transfer stage 21 can be detected.

It is noted that the number of the sub area obtained from the captured image obtained by using the image capturing part 31 may also be one. The sub area obtained by the detection part 35 may include a frame-shaped sub area provided in a frame shape along an end of the electrode formation surface CPa, for example, and may also be a grid-shaped sub area or a cross-like sub area combining band-shaped sub areas. The images of multiple sub areas are individually captured by multiple cameras prepared for the respective sub areas.

The control part 37 controls the inclination adjustment mechanism 15 of the conveyance unit 10 based on the inclination detected by the detection part 35. That is, the control part 37 changes the inclination of the holding surface 13a with respect to the transfer stage 21.

Each of the detection part 35 and the control part 37, for example, is a computer in which a predetermined program is installed, that is, a combination of hardware and software. The detection part 35 and the control part 37 may both be formed by individual programs installed to one computer, or the detection part 35 and the control part 37 may also both be formed by one program installed to one computer.

The mounting unit 40 mounts the electronic component CP to the substrate BD. The electronic component CP is soldered to the substrate BP by a flip chip bonding method. The electronic component CP is equivalent to an example of a mounted object according to the invention, and the substrate BD is equivalent to an example of a target according to the invention.

The mounting unit 40 includes the mounting stage 41. The substrate BD is placed on the placement surface 41a of the mounting stage 41. The mounting stage 41 is provided with a temperature control part (such as a heater). The electronic component CP is pressed against the substrate BD on the mounting unit 40 by using the conveyance unit 10, and the electrode formation surface CPa of the electronic component CP is soldered to the mounting surface BDa of the substrate BD. That is, in the flip chip bonding method, the holding tool 13 is equivalent to a bonding tool mounting the electronic component CP to the substrate BD.

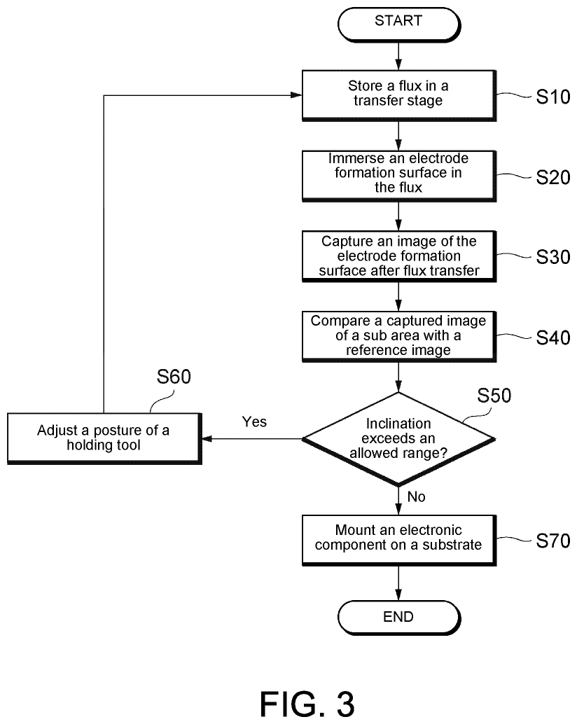

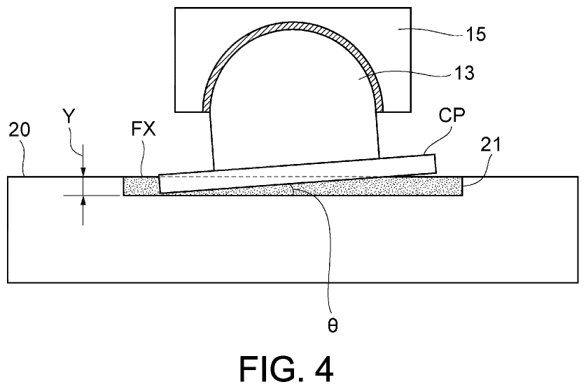

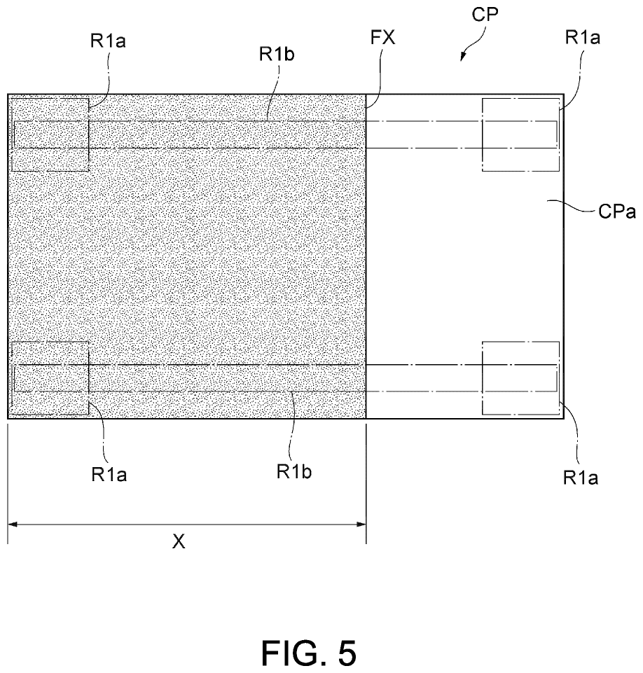

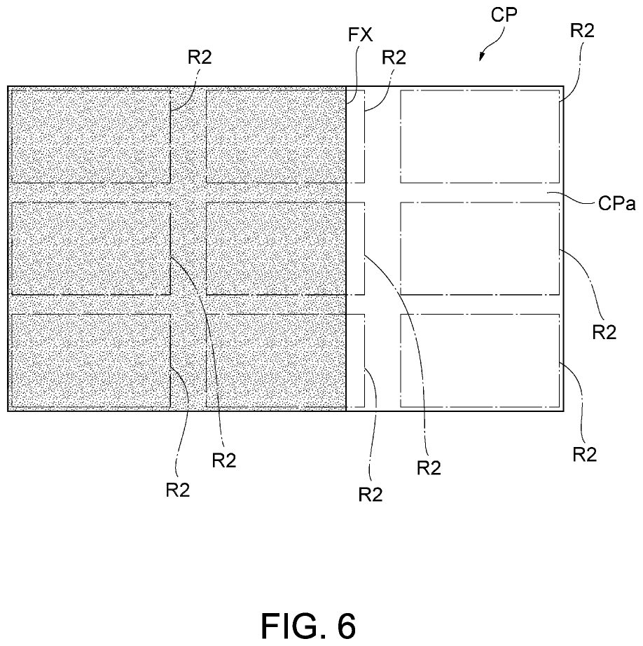

Then, a flux transfer method using the flux transfer apparatus 1 according to the first embodiment is described with reference to FIGS. 3 to 6. FIG. 3 is a flowchart schematically illustrating a flux transfer method using the flux transfer apparatus according to the first embodiment. FIG. 4 is a schematic view illustrating Step S20. FIG. 5 is a view illustrating an example of the captured image of the electrode formation surface and the sub area. FIG. 6 is a view illustrating another example of the captured image of the electrode formation surface and the sub area.

Firstly, the flux FX is stored in the transfer stage 21 (S10). The flux FX is coated on the transfer surface 21a of the transfer stage 21 by using a first squeegee. At this time, the flux FX fills the inside of the immersion area 23. Then, excessive flux FX provided on the outer side of the immersion area 23 is removed by using a second squeegee.

Then, the electrode formation surface CPa is immersed into the flux FX (S20). The electronic component CP held by the holding tool 13 is pressed against the flux FX, and the electrode formation surface CPa is immersed into the flux FX. Then, the electronic component CP is pulled up from the immersion area 23. The flux FX is transferred onto the electrode formation surface CPa, and the shape of the electrode formation surface CPa is transferred onto the flux FX on the transfer stage 21 like being embossed.

As shown in FIG. 4, in the case where the holding tool 13 is inclined at an angle 0 with respect to the transfer stage 21, a region in which the flux FX is transferred and a region in which the flux is not transferred are provided on the electrode formation surface CPa of the electronic component CP.

Then, the image of the electrode formation surface CPa after flux transfer is captured (S30). The conveyance unit 10 is moved from the above of the transfer unit 20 to the above of the posture control unit 30. The electrode formation surface CPa of the electronic component CP held by the holding tool 13 is illuminated with light from the lighting 33. The image of the electrode formation surface CPa that is illuminated is captured by using the image capturing part 31, and the captured image of the electrode formation surface CPa in which the flux FX is transferred to at least a portion thereof is obtained.

The position information of a bump electrode, etc., may also be obtained from the captured image of the electrode formation surface CPa obtained in Step S30. Here, the alignment at the time when the electronic component CP is mounted to the substrate BD may also be performed by using the obtained position information of the bump electrode, etc.

Then, the captured image of the sub area and the reference image are compared (S40). From the captured image obtained in Step S30, a captured image of an arbitrary sub area is obtained. From the reference image (the electrode formation surface of the electronic component after the flux is transferred normally) recorded in advance, the reference image of the sub area is obtained. The captured image and the reference image of each sub area are compared, and the transfer amount, the transfer position of the flux FX in the sub area are detected.

In the example shown in FIG. 5, the captured images of sub areas R1a and R1b are obtained from the captured image of the entire electrode formation surface CPa. The sub area R1a is a corner sub area provided at each of four corners of the electrode formation surface CPa. The sub area R1b is a band-shaped sub area provided over substantially the entire width of the short side direction along the long side of the electrode formation surface CPa. For example, by determining whether the transfer of the flux FX is successful for each sub area R1a as the corner sub area, the orientation of the inclination of the holding tool 13 with respect to the transfer stage 21 can be detected. In addition, by determining the position of the end of the region in which the flux FX is transferred for the sub area R1b that is a band-shaped sub area, the angle θ of the inclination of the holding tool 13 with respect to the transfer stage 21 can be calculated. Specifically, when the depth of the immersion area 23 is set as Y, and the length of the region in which the flux FX is transferred is set as X, the angle θ can be calculated by using a formula as follows:

### sin θ=Y/X

It is noted that the comparison between the captured image and the reference image for the corner sub area and the comparison between the captured image and the reference image for the band-shaped sub area may be carried out simultaneously, and may also be carried out one after another. Specifically, it may also be that whether the holding tool 13 is inclined with respect to the transfer stage 21 is detected through the comparison between the captured image and the reference image for the corner sub area, and then whether a band-shaped sub area is obtained is determined. For example, in the case where an inclination exceeding an allowed range is not detected through the comparison between the captured image and the reference image for the corner sub area, the obtaining of the sub area may be omitted, and in the case where an inclination exceeding the allowed range is detected, a band-shaped sub area having a long side in a direction suitable for calculating the angle θ may be obtained. In addition, it may also be that the obtaining of the corner sub area is omitted, and, the presence/absence, the orientation, the angle, etc., of the inclination of the holding tool 13 with respect to the transfer stage 21 are detected through the comparison between the captured image and the reference image for the band-shaped sub area.

As in the example shown in FIG. 6, multiple sub areas R2 arranged side-by-side in a matrix shape may also be obtained from the captured image of the entire electrode formation surface CPa.

Then, whether the inclination exceeds the allowed range is determined (S50).

In the case where it is determined that the inclination exceeds the allowed range in Step S50, the posture of the holding tool 13 is controlled (S60). In other words, in the case where a transfer defect of the flux FX to the electrode formation surface CPa is detected, the control part 37 controls the inclination adjustment mechanism 15 of the conveyance unit 10 based on the inclination of the holding surface 13a with respect to the transfer stage 21 detected by the detection part 35. For example, the control part 37 may automatically control the inclination adjustment mechanism 15 of the conveyance unit 10. In addition, it may also be that the control part 37 displays on a display the orientation or the size of the inclination of the holding surface 13a with respect to the transfer stage 21 detected by the detection part 35, and controls the inclination adjustment mechanism 15 of the conveyance unit 10 based on a control parameter that is input manually.

After the inclination of the holding surface 13a with respect to the transfer stage 21 is adjusted to substantially zero by using the inclination adjustment mechanism 15, the electronic component CP is conveyed to the transfer unit 20, and the electrode formation surface CPa is immersed into the flux FX stored in the transfer stage 21 again. At this time, although the flux FX is newly stored again, the initially stored flux FX may also be used again.

It is noted that, the operation of the flux transfer apparatus 1 after the inclination of the holding surface 13a with respect to the transfer stage 21 is adjusted to substantially zero by using the inclination adjustment mechanism 15 is not limited to the above. It may also be that the electronic component CP is conveyed to a collection tray and released from the holding tool 13. and flux transfer starts again by using another electronic component.

In the case where it is determined that the inclination does not exceed the allowed range, the electronic component CP is mounted to the substrate BD (S70). In other words, in the case where the flux FX is evenly transferred onto the electrode formation surface CPa, the conveyance unit 10 conveys the electronic component CP to the above of the mounting unit 40, and presses the electronic component CP against the substrate BD. The substrate BD is heated, and the electronic component CP is soldered to the substrate BD.

As described above, the flux transfer apparatus 1 has the image capturing part 31 obtaining the captured image of the electrode formation surface CPa of the electronic component CP after flux transfer, and includes the detection part 35 detecting the inclination of the holding surface 13a with respect to the transfer stage 21 based on the captured image of the electrode formation surface CPa.

In this way, for example, by repetitively carrying out test production, so that the inclination of the holding surface 13a with respect to the transfer stage 21 is substantially zero, the transfer defect of the flux FX can be suppressed. In particular, in the case where the size of the electronic component CP is large, that is, in the case where the inclination of the holding surface 13a with respect to the transfer stage 21 has a significant influence on the transfer defect of the flux FX at the end of the electrode formation surface CPa, the transfer defect can be effectively suppressed.

The flux transfer apparatus 1 includes the inclination adjustment mechanism 15 configured to be able to adjust the posture of the holding tool 13. In this way, the variation of the liquid surface of the flux FX due to a posture change of the transfer stage 21 can be suppressed. Therefore, the occurrence of a transfer defect due to a posture change of the transfer stage 21 can be suppressed.

The image capturing part 31 captures the image of the electrode formation surface CPa of the electronic component CP after flux transfer from the bottom. In this way, based on the captured image obtained by the image capturing part 31, not only the inclination of the holding surface 13a with respect to the transfer stage 21 can be detected, a position deviation of the electronic component CP in an in-plan direction of the electrode formation surface CPa can also be detected. Therefore, the position deviation of the electronic component CP with respect to the substrate BD can also be corrected.

The detection part 35 compares the captured image and the reference image obtained from the electrode formation surface of the electronic component after the flux is normally transferred. In this way, even for a flux having low visibility and being difficult to detect through an image analysis, the detection can be accurately carried out by using an image analysis on the differential between the captured image and the reference image.

The detection part 35 compares the captured image and the reference image for at least one sub area. In this way, compared with the case where the captured image of the entire electrode formation surface CPa is compared with the reference image, the time required for detection can be reduced.

The sub areas obtained by the detection part 35 include the corner sub area. In this way, when the inclination of the holding tool 13 with respect to the transfer stage 21 changes, by determining whether the transfer of the flux FX at the corner sub area with the greatest displacement is successful, the transfer defect of the flux FX on the entire electrode formation surface CPa can be quickly evaluated.

The sub areas obtained by the detection part 35 include the belt-shaped sub area. In this way, by specifying the position of a transfer flux defect in the belt-shaped sub area, the angle of the inclination of the holding surface 13a with respect to the transfer stage 21 can be calculated.

By transferring the flux FX to the electrode formation surface CPa of the electronic component CP by using the flux transfer apparatus 1, the transfer defect of the flux FX can be suppressed.

After the inclination of the holding surface 13a with respect to the transfer stage 2 1 is detected in the detection part 35, the electrode formation surface CPa of the electronic component CP is again immersed into the flux FX stored in the transfer stage 21. In this way, by reusing the electronic component CP in which the transfer of the flux FX is insufficient, the loss of the electronic component CP can be reduced.

After the inclination of the holding surface 13a with respect to the transfer stage 2 1 is detected in the detection part 35, the electronic component CP may also be released without being mounted to the substrate BD.

In the following, other embodiments are described. The same or similar reference numerals used to label the same or similar configurations as those shown in FIGS. 1 to 6, and the description thereof will be omitted as appropriate. Moreover, the same actions and effects due to the same configuration are not mentioned one by one.

### Embodiment 2

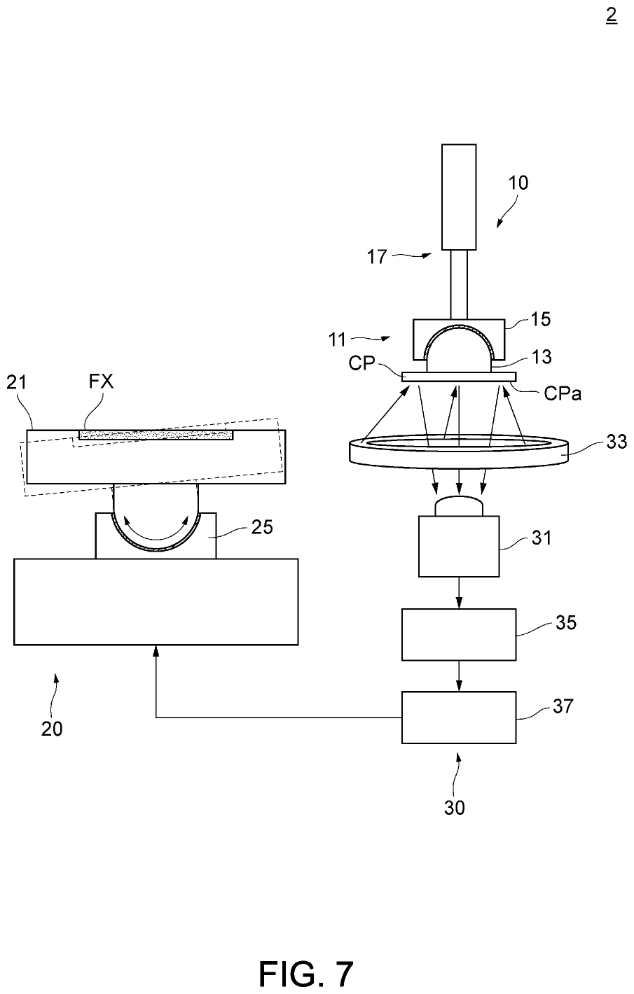

In the following, the configuration of a flux transfer apparatus 2 according to the second embodiment is described with reference to FIG. 7. FIG. 7 is a schematic view illustrating a configuration of a posture control unit according to the second embodiment.

In the second embodiment, the transfer unit 20 includes an inclination adjustment mechanism 25.

The inclination adjustment mechanism 25 is configured to be able to adjust the posture of the transfer stage 21. The inclination adjustment mechanism 25, for example, sets the posture of the transfer stage 21 with respect to the holding tool 13, so that the surface of the flux FX stored in the transfer stage 21 and the electrode formation surface CPa of the electronic component CP can be substantially parallel to each other. The posture of the transfer stage 21 with respect to the holding tool 13, for example, is defined as the inclination of the transfer surface 21a of the transfer stage 21 with respect to the holding surface 13a of the holding tool 13. The inclination adjustment mechanism 25 is equivalent to an example of a second adjustment part according to the invention.

The posture control unit 30 detects the inclination of the holding surface 13a with respect to the transfer stage 21, and a control part 37 controls the inclination adjustment mechanism 25 of the transfer unit 20, so that the inclination is substantially zero. The inclination adjustment mechanism 15 of the conveyance unit 10 is set so that the inclination of the holding surface 13a with respect to the mounting stage 41 is substantially zero. In this way, the inclination of the holding tool 13 with respect to the transfer stage 21 can be adjusted without adjusting the posture of the holding tool 13. Therefore, the occurrence of the inclination of the electronic component CP with respect to the substrate BD due to a displacement error at the time of adjusting the posture of the holding tool 13 can be suppressed.

The control part 37 of the posture control unit 30 may also control both of the inclination adjustment mechanism 15 of the conveyance unit 10 and the inclination adjustment mechanism 25 of the transfer unit 20.

### Embodiment 3

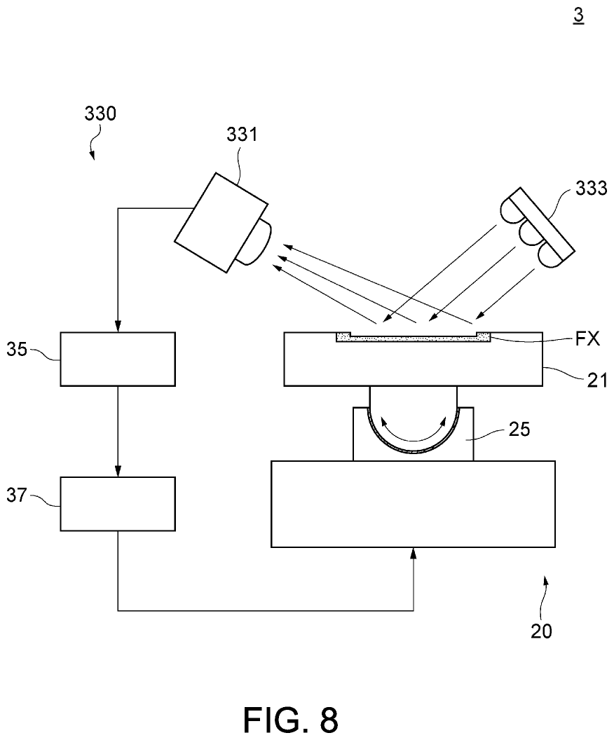

In the following, the configuration of a flux transfer apparatus 3 according to the third embodiment is described with reference to FIG. 8. FIG. 8 is a schematic view illustrating a configuration of a posture control unit according to the third embodiment.

In the third embodiment, a posture control unit 330 includes a lighting 333 and an image capturing part 331 provided above the transfer stage 21. The lighting 333 illuminates the transfer stage 21 after flux transfer with light, and the image capturing part 331 captures an image of the surface of the flux FX on the transfer stage 21 after flux transfer. In the detection part 35, the captured image obtained by the image capturing part 331 and the reference image of the surface of the flux FX on the transfer stage 21 after the flux FX is normally transferred are compared. In the flux FX on the transfer stage 21 after flux transfer, an unevenness is formed in accordance with the shape of the electrode formation surface CPa of the electronic component CP. Therefore, by obtaining the captured image of the flux FX on the transfer stage 21 and performing image analysis, the transfer condition of the flux FX to the electrode formation surface CPa can be detected. The control part 37 may control the inclination adjustment mechanism 25 of the transfer unit 20, and may also control the inclination adjustment mechanism 15 of the conveyance unit 10.

As described above, according to an aspect of the invention, a flux transfer apparatus, a flux transfer method, and a mounting apparatus capable of suppressing transfer defects can be provided.

The embodiments described above are for facilitating the understanding of the invention, and are not intended to limit the interpretation of the invention. Each element included in the embodiment and its arrangement, materials, conditions, shape, size, etc. are not limited to those illustrated and can be changed as appropriate. Also, it is possible to partially replace or combine the configurations shown in different embodiments.

### REFERENCE SIGNS LIST

1: Flux transfer apparatus;
10: Conveyance unit;
11: Bonding head;
13: Holding tool;
15: Inclination adjustment mechanism;
17: Actuator;
20: Transfer unit;
21: Transfer stage;
32: Immersion area;
25: Inclination adjustment mechanism;
30: Posture control unit;
31: Image capturing part;
33: Lighting;
35: Detection part;
37: Control part;
40: Mounting unit;
41: Mounting stage;
FX: Flux;
CP: Electronic component;
PCa: Electrode formation surface;
BD: Substrate.

1. A flux transfer apparatus, transferring a flux to an electrode formation surface of an electronic component, the flux transfer apparatus comprising:
a transfer stage, storing the flux;
a holding tool, holding the electronic component by using a holding surface, so that the electrode formation surface of the electronic component is immersed into the flux stored in the transfer stage;
an image capturing part, obtaining a captured image of at least one of the electrode formation surface of the electronic component after flux transfer and the transfer stage after flux transfer; and
a detection part, detecting a degree of parallelism of the holding surface with respect to the transfer stage based on the captured image.

2. The flux transfer apparatus as claimed in claim 1, further comprising a first adjustment part configured to be able to adjust a posture of the holding tool based on the degree of parallelism.

3. The flux transfer apparatus as claimed in claim 1, further comprising a second adjustment part configured to be able to adjust a posture of the transfer stage based on the degree of parallelism.

4. The flux transfer apparatus as claimed in claim 1, wherein the image capturing part captures an image of the electrode formation surface of the electronic component after flux transfer from a bottom.

5. The flux transfer apparatus as claimed in claim 4, wherein the detection part compares the captured image and a reference image obtained from an electrode formation surface of an electronic component after a flux is normally transferred.

6. The flux transfer apparatus as claimed in claim 5, wherein the detection part obtains an image of at least one sub area from the captured image, and performs comparison with the reference image for the at least one sub area.

7. The flux transfer apparatus as claimed in claim 6, wherein the at least one sub area comprises a corner sub area provided at a corner of the electrode formation surface.

8. The flux transfer apparatus as claimed in claim 6, wherein the at least one sub area comprises a band-shaped sub area extending along a long side or a short side of the electrode formation surface.

9. The flux transfer apparatus as claimed in claim 1, wherein the holding tool is a bonding tool mounting the electronic component to a target.

10. A flux transfer method for transferring a flux to an electrode formation surface of an electronic component, the flux transfer method comprising:
storing the flux in a transfer stage;
holding the electronic component by using a holding surface of a holding tool;
immersing the electrode formation surface of the electronic component into the flux stored in the transfer stage;
obtaining a captured image of at least one of the electrode formation surface of the electronic component after flux transfer and the transfer stage after flux transfer; and
detecting a degree of parallelism of the holding surface with respect to the transfer stage based on the captured image.

11. The flux transfer method as claimed in claim 10, further comprising adjusting a posture of the transfer stage or the holding tool based on the degree of parallelism.

12. The flux transfer method as claimed in claim 11, further comprising: releasing the electronic component without mounting the electronic component to a target, and immersing an electrode formation surface of another electronic component into the flux stored in the transfer stage.

13. The flux transfer method as claimed in claim 11, further comprising: immersing the electronic component into the flux stored in the transfer stage again.

14. A mounting apparatus, mounting an electronic component in which a flux is transferred onto an electrode formation surface to a target, the mounting apparatus comprising:
a transfer stage, storing the flux;
a mounting tool, holding the electronic component by using a holding surface, so that the electrode formation surface of the electronic component is immersed into the flux stored in the transfer stage, and mounting the electronic component to the target;
an image capturing part, obtaining a captured image of at least one of the electrode formation surface of the electronic component after flux transfer and the transfer stage after flux transfer; and
a detection part, detecting a degree of parallelism of the holding surface with respect to the transfer stage based on the captured image.
